(19) United States
(12) Patent Application Publication
(10) Pub. No.: US 2006/0285350 A1
(43) Pub. Date: Dec. 21, 2006

(54) A Lighting System for Navigational Aids

(75) Inventor: Sean Xiaolu Wang, Wilmington, DE (US)

Correspondence Address: BWT PROPERTY, INC., 19 SHEA WAY, SUITE 301, NEWARK, DE, 19713, US

(73) Assignee: BWT PROPERTY, INC., Newark, DE (US)

(21) Appl. No.: 11/424,704

(22) Filed: Jun. 16, 2006

Related U.S. Application Data
(66) Substitute for application No. 60/595,248, filed on Jun. 17, 2005.

(51) Int. Cl. H01L 33/00

(52) U.S. Cl. 362/555; 362/556

(57) ABSTRACT

This invention relates to a fiber optic lighting system (FOLS), in which optical fibers, including regular optical fibers and side emitting optical fibers, are used to provide lighting and signaling for navigational aids. The FOLS also serves as a sensor network which monitors the environment as well as the condition of the lighted field.

### REFERENCE TO RELATED APPLICATIONS

This application claims an invention which was disclosed in Provisional Patent Application No. 60/595,248, filed Jun. 17, 2005, entitled “A Fiber Optic Lighting System for Navigational Aids”. The benefit under 35 USC §119(e) of the above mentioned United States Provisional Applications is hereby claimed, and the aforementioned application is hereby incorporated herein by reference.

### FIELD OF THE INVENTION

The present invention relates generally to a lighting system and more specifically to a fiber optic lighting system for navigational aids.

### BACKGROUND

Lighting is an integral part of airport safety system, providing guidance, signaling, and demarcation of runways and taxiways. The lighting system includes those elevated/in-pavement taxiway and runway lights, medium and high intensity approach lights. These lights can be further configured as edge, centerline, threshold/end, approach, hold-line, stop bar, and runway guard lights, etc. The lighting system is also necessary for navigation aids in helipads, seaplane base landing areas, emergency evacuation routes, and pedestrian crossings, as well as aid to search and rescue operations, and marine waterways that include buoys, ranges, bridges and obstructions.

The current airport lighting systems utilize conventional incandescent lights, which are power consuming and short in lifetime. The rapid development of solid sate lighting apparatus such as light emitting diodes (LEDs) provides a potential replacement for the conventional incandescent lights as they have high energy efficiency, long lifetime, low maintenance cost, enhanced reliability and durability, and no lumen loss induced by filtering. To provide lighting for the airport demarcation line, one method is to use multiple LEDs to define the illumination pattern. An example can be found in U.S. Pat. No. 6,354,714 to Rhodes, which is hereby incorporated herein by reference. This approach requires a large number of LEDs, which increases the probability of system failure. In another approach, the demarcation pattern is generated by light projection method using lenses in combination with a few LEDs or lasers. An example can be found in U.S. Pat. No. 6,688,755 to O'Meara, which is hereby incorporated herein by reference. The drawback of this approach is that the brightness of the generated pattern is highly dependent on the surface conditions, such as color, absorbance, and roughness of the runway or landing zone.

It is thus the objective of the present invention to provide a lighting and demarcation system that is robust and relatively insensitive to surface conditions of the lighted field. The lighting system employs solid state lighting apparatus such as LEDs or lasers as the light source and optical fibers, preferably side emitting optical fibers for light delivery. Applications of the disclosed fiber optic lighting system (FOLS) include airport lighting, maritime lighting, emergency zone lighting, search and rescue signaling, etc.

### BRIEF DESCRIPTION OF THE FIGURES

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present invention.

FIG. 1 shows a side emitting optical fiber cable that is used to build the fiber optic lighting system (FOLS).

FIG. 2 illustrates an example of using the side emitting fiber cable for airport edge lighting and threshold lighting.

FIG. 3 illustrates that the FOLS can be deployed into different patterns for specific applications such as for helicopter landing pad lighting.

FIG. 4 illustrates that by attaching a special diffusive optic component at the end of FOLS, it becomes a laser strobe light, which can be used for signal lighting such as for airport approach lighting.

FIG. 5 illustrates an example of illumination pattern generation using mixed side emitting fibers and regular end emitting fibers.

FIG. 6 illustrates an example of hold-line pattern generation using mixed side emitting fibers and regular end emitting fibers.

FIG. 7 illustrates an example of a multi-wavelength, multi-pattern lighting system comprising mixed side emitting fibers and regular end emitting fibers.

FIG. 8 illustrates a method to increase the robustness of the FOLS by adding redundant light sources.

FIG. 9a illustrates an example of utilizing the FOLS as a sensor network to monitor the conditions of the environment and the lighted field.

FIG. 9b illustrates the light flow in the FOLS sensor network of FIG. 9a.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

Before describing in detail embodiments that are in accordance with the present invention, it should be observed that the embodiments reside primarily in combinations of method steps and apparatus components related to a fiber optic lighting system for navigational aids. Accordingly, the apparatus components and method steps have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

In this document, relational terms such as first and second, top and bottom, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element.

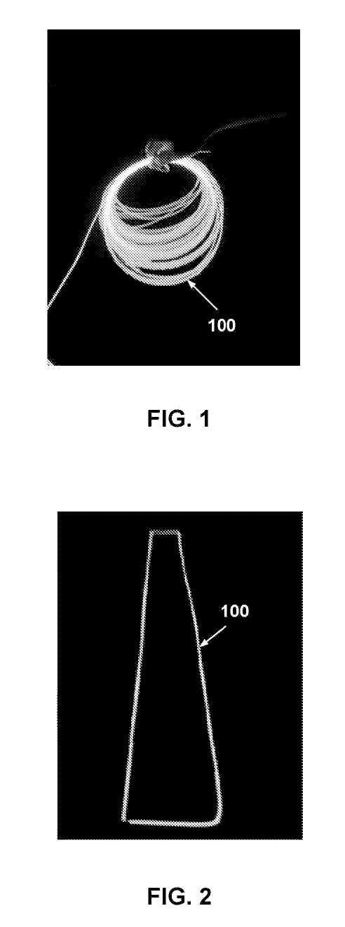

In one preferred embodiment of the present invention, the fiber optic lighting system (FOLS) comprises a laser light source and a side emitting optical fiber. The laser can be a laser diode (LD), a diode pumped solid state (DPSS) laser, a gas laser or other kind of lasers. The side emitting fiber comprises a core region and a cladding region. Unlike regular optical fibers, imperfections and micro-structures are introduced at the boundary of the core and cladding region of the side emitting fiber so that light can refract out of the fiber from its side surface. By controlling the level of imperfections, the unit loss of the fiber can be managed to meet for different fiber length requirements. Fiber cables that run in excess of 1,000 meters are possible. FIG. 1 shows a side emitting optical fiber cable 100 which is illuminated with a green DPSS laser at a wavelength of 532 nm. The fiber is highly flexible and can be wrapped around a small diameter to form any desired illumination pattern. FIG. 2 illustrates an example of using the side emitting fiber for airport edge lighting and threshold lighting. In FIG. 2, a rectangle shaped runway or taxiway is defined by the side emitting fiber 100, whose visibility can be controlled by adjusting the power of the laser light source. The advantages of the fiber optic lighting system lie in its flexibility, light weight, high strength, low cost, relative insensitivity to surface condition and operating environment, and compatibility with existing lighting system. The optical fiber 100 is formed by a thin strand of fused silica or plastic material which is inherently lightweight. A 1000 m length of fiber cable weighs only about several pounds. Moreover, the fiber is highly flexible and can be bent over very small diameters. All these features make the fiber lighting system handily portable and easy for installation and deployment. The fiber cable 100 contains no electrical wires, which makes it safe to be installed under water or on the water surface, or even under environment with highly flammable gases. The illuminating light is guided in the fiber cable. So the visibility of the lighting system will not be influenced by the condition (such as vegetation, color, roughness) of the surface it is mounted on. The fiber cable is protected by high strength polymer and is immune to corrosions. Thus it can be installed under the most adverse operating environments. The cost of the fiber cable 100 is potentially very low and can be made as a disposable item.

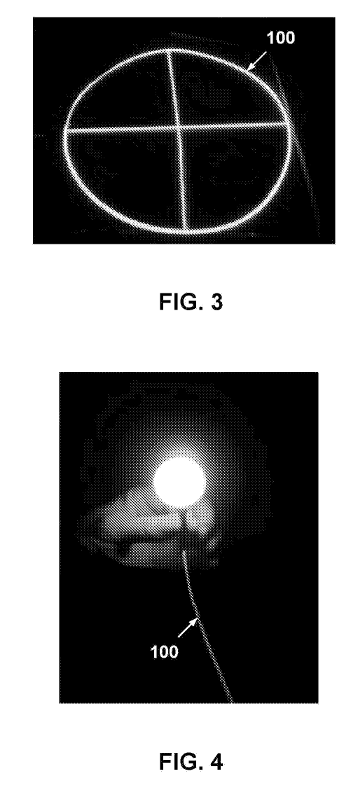

The FOLS can be easily deployed into difference shapes to adapt for different lighting applications. One example is illustrated in FIG. 3, where the side emitting fiber 100 is configured to form a pattern for helicopter landing pad lighting. Besides its side illuminating function, the fiber cables used in the FOLS can also transmit light for end emitting. By attaching certain optical components such as lens, mirrors, and/or diffractive beam steering elements at end of the fiber cable for illumination pattern control, the FOLS can be configured as elevated signal lighting apparatus with unidirectional, bidirectional, or omni-directional lighting capability. Referring to FIG. 4, a diffusive optical component is attached at the end of a side emitting fiber 100 so that it becomes a laser strobe light, which can be used for signal lighting such as airport approach lighting.

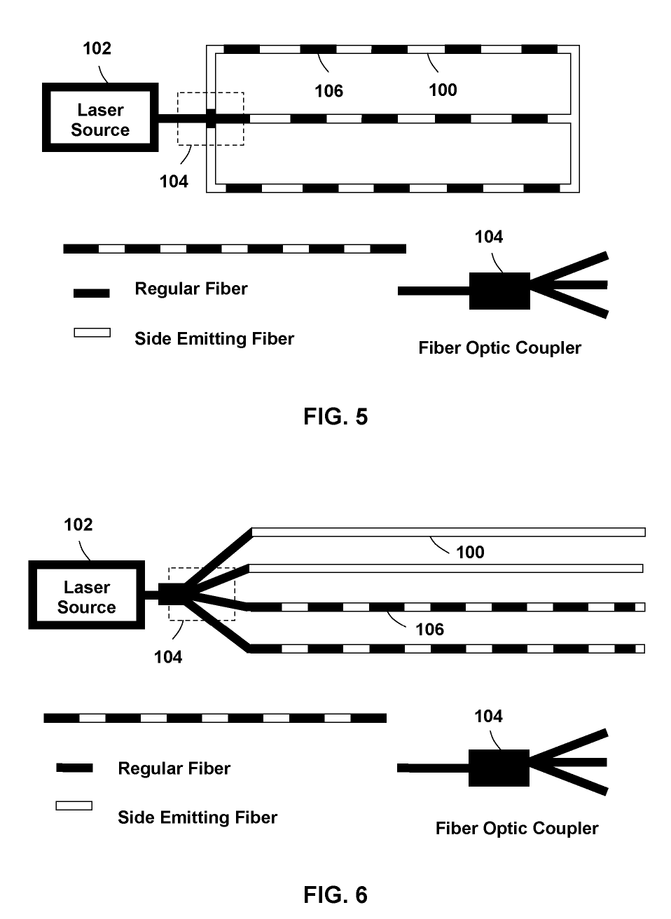

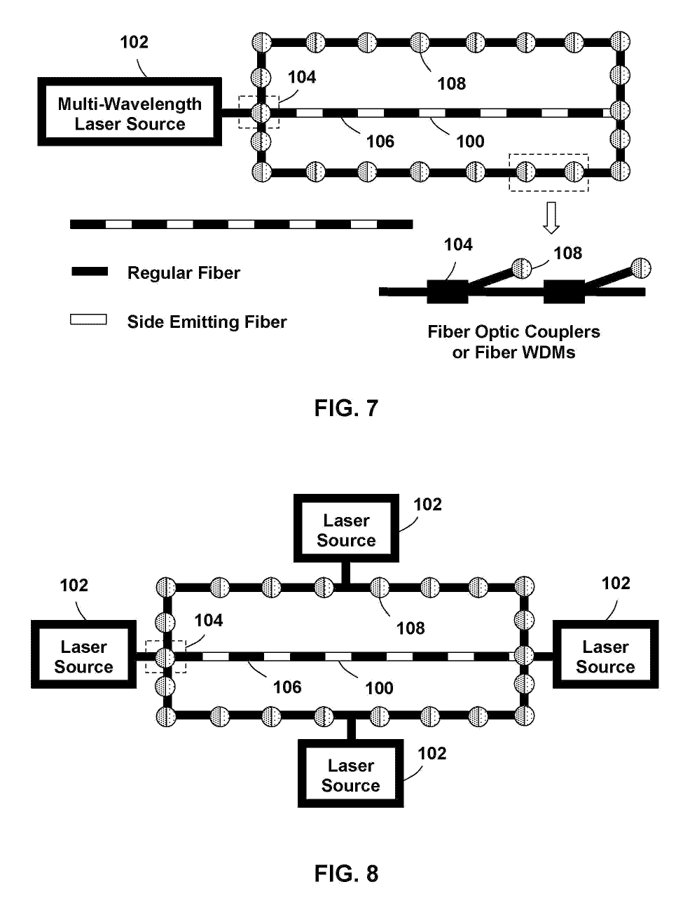

Even more complicated patterns may be generated by combining side emitting fibers with regular end emitting optical fibers. One way to achieve this is to control the imperfection level of the side emitting fiber in a manner that certain sections of the fiber emit light from the side surface while the other sections do not. Another method is to fusion splice side emitting fibers with regular optical fibers. Some examples of the combined fiber optic lighting system are shown in FIG. 5, FIG. 6, FIG. 7 and FIG. 8, respectively. In FIG. 5, the illuminating light from the laser source 102 is split into three fiber cables using a fiber coupler 104. The three fiber cables are composed of sections of regular fibers 106 and side emitting fibers 100 to form the desired illumination pattern. In FIG. 6, a hold-line pattern is generated by using mixed side emitting fibers 100 and regular fibers 106 or by using only side emitting fiber 100 but burying certain sections of the fiber into the pavement to form the desired pattern. In FIG. 7, the light source 102 is a multi-wavelength laser or an array of lasers with different wavelengths. The laser light in different wavelengths is coupled into different fiber cables that bundled together or coupled into the same fiber cable by using wavelength division multiplexing technology. In the later case, the light in a specific wavelength can be coupled into or out of the fiber cable using fiber wavelength division multiplexers (WDMs). Referring to FIG. 7, the illuminating light from a multi-wavelength laser source 102 is distributed into different fiber cables of FOLS through fiber optic couplers or WDMs 104. Some of the fiber cables are configured to be emitting from their end surfaces 108 in a way similar to that shown in FIG. 4 and the other fiber cables are configured to be side emitting in a way similar to that shown in FIG. 1. Thus a multi-wavelength, multi-pattern illuminating system is formed. The wavelength of the laser source 102 may be switched (such as from green to red) as illustrated in the figure to indicate different status of the airfield. Another way to create a multi-wavelength illuminating system is to coat different fluorescence materials on the side or end of the fiber cable so that they emit different wavelengths under illumination from the same light source. The light source may also emit light in the infrared wavelength region to provide lighting for pilots wearing night vision goggles (NVGs). To increase the robustness of the system, multiple redundant laser sources can be integrated into the same FOLS as shown in FIG. 8 so that fiber breakage will not influence the proper functionality of the lighting system.

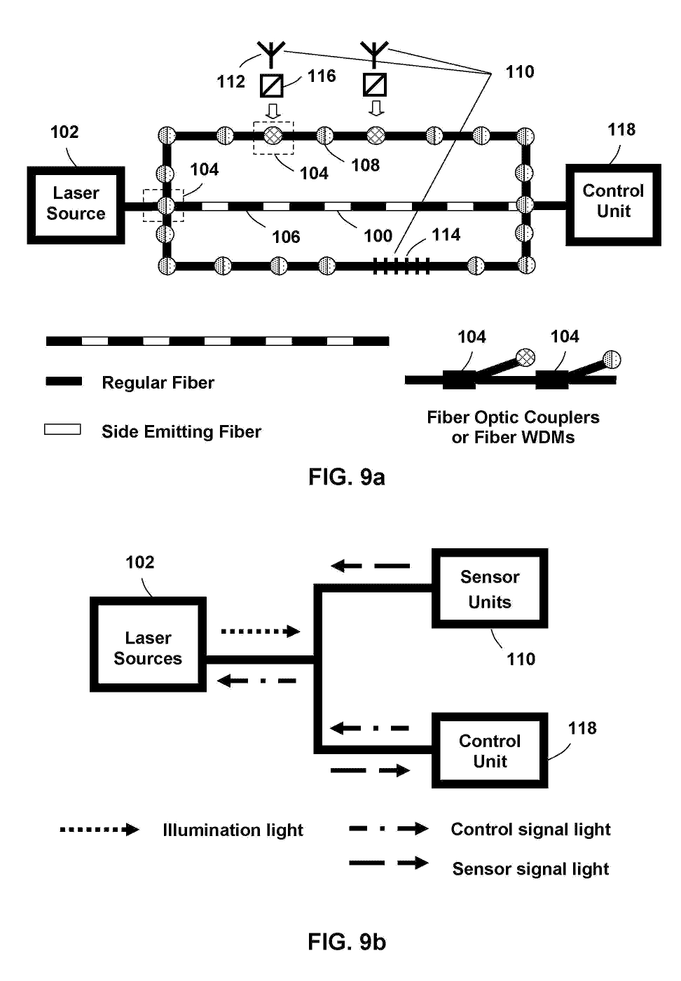

Another aspect of the present invention is to utilize the FOLS as a sensor network to monitor the condition of the airfield. A schematic illustration of the sensor network is shown in FIG. 9a. Referring to the figure, the condition of the airfield is measured by a plurality of sensor units 110, which may comprise conventional sensors 112, such as motion sensors, video cameras, thermometers, photo detectors, smoke, pressure, and vibration sensors, etc. or fiber optic sensors 114, such as fiber Bragg gratings or long period gratings that can be directly implemented on the fiber cables. In the first case, electrical-optical (E-O) converters 116 are used to convert the sensor signal from electronic domain into optical domain and couple it into the fiber cables of FOLS through fiber optic couplers or WDMs 104 for transmission. The sensor signal may be transmitted to a control unit 118 which may or may not be co-located with the laser sources to monitor and control the operation of FOLS. In this configuration, lights in two or more different wavelengths propagate simultaneous in the fiber cable. Some wavelengths are used for illumination while the other wavelengths are used to transmit the sensor and/or control signal. In other embodiments, the sensor signal may also be transmitted in different fiber cables and/or in different modulation formats. FIG. 9b illustrates the light flow in the FOLS based lighting and sensor network. Different shaped lines in the figure represent light in different fiber cables, wavelengths, and/or modulation formats. The sensor units 110 and the control unit 118 allow the illumination pattern of FOLS to be adjusted according to environment conditions. For example, the control unit 118 may adjust the intensity of the laser sources 102 according to visibility of the airfield, which is determined by photo detectors measuring stray lights from the environment. In another application, the sensor system may be utilized to prevent runway/taxiway incursion as the sensor units 110 can detect the movement of the aircraft through motion detection, video monitoring, or vibration sensing. In case of incursion, the control unit can send alarm signal to the operator or to the pilot through the FOLS by modulating the intensity or varying the wavelength of the illumination light.

For the lighting system that uses large quantity of individual LEDs or lasers to form the illumination pattern, a totally new electrical driving system has to be installed as the driving voltage and driving current for the LEDs and lasers are incompatible with the existing airport electrical systems. To the contrary, the FOLS only requires limited number of light sources. Thus its electrical driving circuit can be easily integrated into the existing electrical systems, which greatly reduces its installation cost.

The application of FOLS is not limited to airport lighting. It can also be used for sub-sea grid lighting, driver return path lighting, pedestrian cross lighting, exclusion zone lighting, emergency runway lighting, search and rescue signaling, etc.

In the foregoing specification, specific embodiments of the present invention have been described. However, one of ordinary skill in the art appreciates that various modifications and changes can be made without departing from the scope of the present invention as set forth in the claims below. For example, the fiber cable used in FOLS is not limited to a specific kind of fiber cable. The light source is not limited to the present-day LEDs or lasers. The FOLS sensor network may comprise other kinds of sensor units. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

What is claimed is:

1. A fiber optic lighting system capable of illuminating a field for navigational aids, the lighting system comprising:
a) at least one solid state lighting apparatus to generate illuminating light in the visible and/or infrared wavelengths; and
b) at least one optical fiber cable for carrying the illuminating light generated by said solid state lighting apparatus and illuminating a field for navigational aids.

2. The lighting system of claim 1, wherein the solid state lighting apparatus comprises at least one light emitting diode (LED).

3. The lighting system of claim 1, wherein the solid state lighting apparatus comprises at least one laser.

4. The lighting system of claim 1, wherein the optical fiber cable comprises side emitting fibers.

5. The lighting system of claim 1, wherein the optical fiber cable comprises end emitting fibers.

6. The lighting system of claim 1, further comprising optical fiber couplers for distributing the light of said solid state lighting apparatus into multiple optical fiber cables and/or for coupling part of the light out of the fiber cable for illuminating.

7. The lighting system of claim 1, wherein the solid state lighting apparatus generates light in one wavelength.

8. The lighting system of claim 1, wherein the solid state lighting apparatus generates light in multiple wavelengths.

9. The lighting system of claim 8, wherein the light in different wavelengths are sent into different fiber cables.

10. The lighting system of claim 8, wherein the light in different wavelengths are sent into the same fiber cable.

11. The lighting system of claim 10, further comprising wavelength division multiplexers (WDMs) for selecting the proper wavelength from the illuminating light.

12. The lighting system of claim 1, wherein different sections of the fiber cable are coated with different fluorescence materials to generate light in different wavelengths under the illumination from said solid state lighting apparatus.

13. The lighting system of claim 6, further comprising optical beam manipulating elements at the end of the fiber cables or at the end of the fiber couplers to form elevated signaling lights.

14. The lighting system of claim 1, further comprising sensor units to monitor the conditions of the environment and the illuminated field and to generate sensor signals.

15. The lighting system of claim 14, wherein the sensor signals are converted into optical domain and coupled into fiber cables for transmission.

16. The lighting system of claim 14, wherein the fiber cables used to carry the sensor signals are separate from the fiber cables used to carry the illuminating light.

17. The lighting system of claim 14, wherein the fiber cables used to carry the sensor signals are the same as the fiber cables used to carry the illuminating light, and wherein the sensor signals are carried by light in wavelengths different from the wavelengths of the illuminating light.

18. The lighting system of claim 14, further comprising a control unit, and wherein the control unit generates a control signal to control the operation of the solid state lighting apparatus according to said sensor signals.

19. The lighting system of claim 18, wherein the control unit sends control signals through a fiber cable, and wherein the fiber cable is different from the illuminating fiber cable.

20. The lighting system of claim 18, wherein the control unit sends control signals through a fiber cable, and wherein the fiber cable is the same as the illuminating fiber cable.
